(19) United States
(12) Patent Application Publication
(10) Pub. No.: US 2005/0136576 A1
(43) Pub. Date: Jun. 23, 2005

(54) Plasma treatment method and plasma treatment apparatus

(75) Inventors: Shigenori Ishihara, Moriya-shi (JP); Hirohisa Oda, Yuuki-shi (JP); Yuu Nishimura, Moriya-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/002,903

(22) Filed: Dec. 3, 2004

(30) Foreign Application Priority Data
Dec. 9, 2003 (JP) 409764/2003(PAT.)

(51) Int. Cl. H01L 21/00; H01L 21/84; G02B 5/08; G02B 5/20; F21V 9/04; F21V 9/06; H01L 21/322

(52) U.S. Cl. 438/162; 438/475

(57) ABSTRACT

A substrate to be treated is treated in a vacuum chamber in such a state that a rear surface, opposite to a surface to be treated, of the substrate is disposed toward and upstream direction of a treatment gas containing hydrogen atom, by use of hydrogen plasma of the treatment gas. The plasma treatment is performed in such a state that the substrate to be treated is mounted on a substrate mounting table disposed in the chamber so that a surface of a device structure portion is disposed toward the substrate mounting table side.

### FIELD OF THE INVENTION AND RELATED ART

The present invention relates to a plasma treatment method and a plasma treatment apparatus which perform plasma treatment of a substrate at one surface thereof. Particularly, the present invention relates to a plasma treatment method suitable for terminal treatment of a dangling bond during manufacture of a semiconductor apparatus and a plasma treatment apparatus for carrying out the plasma treatment method.

In a semiconductor apparatus, it haws been known that a number of dangling bonds present at a thin film interface of a silicon-based material or a grain boundary of polycrystalline silicon form a barrier against trap level or movement of a carrier during device operation, thus adversely affecting performances of the apparatus.

For example, it has been known that in a thin film transistor (TFT), dangling bonds which are present at a polysilicon grain boundary cause attenuation of an on-state current, an increase in an off-state current, and an increase in S value. In a charge-coupled device (CCD), it has been known that defects present between silicon and an oxide film increase a dark current.

In order to solve the above described problems, terminal treatment of dangling bond with hydrogen radical is effective, so that annealing treatment in a hydrogen gas atmosphere or hydrogen plasma treatment, e.g., utilizing a reactive ion etching (RIE) apparatus has been most commonly performed.

Of these treatment methods, the hydrogen plasma treatment has a high efficiency and is completed in a short time, so that it haws been widely employed as described in Japanese Laid-Open Patent Application (JP-A) No. Hei 05-243273.

Generally, an effect of the terminal treatment as described above is cancelled by plasma damage, a contamination of metal atom, or high-temperature treatment, so that in many cases, the terminal treatment is carried out not immediately after formation of an objective device structure but after formation of an interlayer insulating film or a passivation film.

When the above described terminal treatment is performed, according to a conventional hydrogen plasma treatment method, treatment has been carried out in such a state that a rear surface of a substrate to be treated (hereinafter, referred to as a “treating substrate) is disposed toward a substrate holding means and a surface (to be treated) at which a device structure is formed is exposed to hydrogen active species, an effect of the terminal treatment cannot be attained in some cases.

For example, when a polyimide film is formed as a passivation film and then the above described plasma treatment is carried out, hydrogen active species reacts with the polyimide, thus failing to reach the device structure. For this reason, the plasma treatment not only has no effect but also causes the polyimide film formed on the device structure to be considerably etched.

The effect of the above described plasma treatment is also not attained when a film of blacking movement of hydrogen active species, such as a titanium nitride film used in an optical black (OPB) portion of a solid-state image sensing device, is disposed on or above the objective device structure.

Accordingly, in the conventional plasma treatment method for achieving the terminal treatment effect, there is a large limitation an applicable device structure and steps.

### SUMMARY OF THE INVENTION

An object of the present invention is to provide a plasma treatment method capable of considerably reducing a limitation on applicable device structure and steps in order to perform terminal treatment with hydrogen plasma.

Another object of the present invention is to provide a plasma treatment apparatus for carrying out the plasma treatment method.

According to an aspect of the present invention, there is provided a plasma treatment method for treating a surface, to be treated, of a substrate by using plasma of a treatment gas comprising at least one species of gas selected from the group consisting of hydrogen gas, water vapor, and ammonia, the method comprising:
a treatment step of treating the substrate in such a state that a rear surface, opposite from the surface to be treated, of the substrate is disposed toward an upstream direction of the treatment gas.

According to another aspect of the present invention, there is provided a plasma treatment apparatus for treating a surface, to be treated, of a substrate, comprising:
a gas supply portion for supplying a treatment gas including hydrogen atom, and
a substrate holding apparatus for holding the substrate so that the surface to be treated is disposed toward an upstream direction of the treatment gas in a chamber.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic view showing a treatment apparatus used in an embodiment of the present invention.

FIG. 2 is a graph showing an etching rate of a polyimide film during hydrogen plasma treatment.

FIGS. 3(a) and 3(b) are views for illustrating a difference in terminal treatment effect with hydrogen plasma with respect to a semiconductor substrate having a surface layer formed of a polyimide film between a conventional plasma treatment method (apparatus) (FIG. 3(a)) and a plasma treatment method (apparatus) of First Embodiment of the present invention (FIG. 3(b)).

FIG. 4 is a view for illustrating a structure of a treating substrate used in Second Embodiment of the present invention.

FIG. 5 is a view for illustrating another embodiment of a substrate holding method in the present invention.

FIG. 6 is a graph showing a relationship between a distance WD between a dielectric window and a treating substrate and a resist film decreasing speed.

FIG. 7 is a graph showing a relationship between a temperature rise of a dielectric window by plasma irradiation and a thermal (heat) conductivity of a dielectric material.

FIGS. 8(a) to 8(e) are schematic views showing examples of slot antenna shapes applicable to the present invention.

FIG. 9 is a graph showing a relationship between ignitability of hydrogen plasma and hydrogen gas pressure with time from microwave radiation.

FIG. 10 is a view showing a batch treatment chamber for illustrating an example of an embodiment of the present invention.

### DETAILED DESCRIPTION OF THE PREFERRED EMBODIMENTS

Hereinbelow, the present invention will be described based an embodiments of the present invention and comparative embodiments with reference to the drawings.

### (First Embodiment and First Comparative Embodiment)

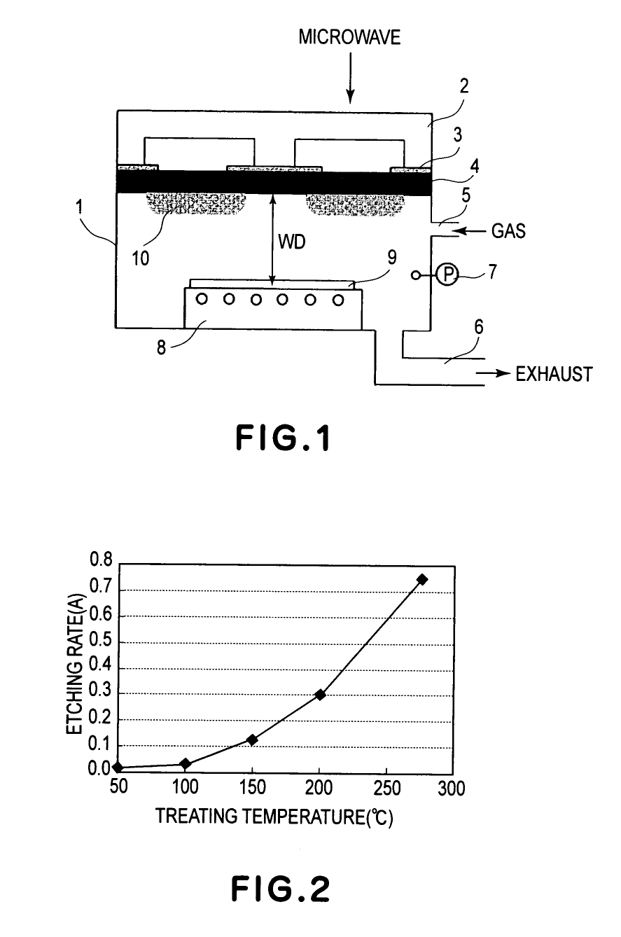

FIG. 1 schematically illustrates a plasma treatment apparatus used in First Embodiment of the present invention.

In a vacuum chamber 1 provided with an exhaust pipe 6 and a treatment gas intake pipe 5, a stage 8 (as a substrate holding means) containing therein a heater is mounted. The vacuum chamber 1 can be kept at a desired pressure while introducing thereinto a treatment gas by a pressure gauge 7 and an exhaust speed-adjusting mechanism (not shown) connected to the exhaust pipe 6.

Further, in the vacuum chamber 1, a dielectric window 4 for incorporating a microwave into the chamber 1 is oppositely disposed to the stage 8 with a distance WD, between the dielectric window 4 and the stage 8, of not less than 50 mm and not more than 150 mm. The microwave supplied from an unshown microwave supply source and an unshown matching mechanism forms an interference wave in an endless circular (microwave) waveguide 2, thus forming a surface interference wave on a vacuum-side surface of the dielectric window 4 via slots provided in a slot antenna 3. By the resultant electric field produced on the dielectric material (window) 4 and the treatment gas, containing at least hydrogen gas, introduced through the treatment gas intake pipe 5, high-density plasma having a density of not less than 1×10¹¹ cm⁻³ is generated only a plasma generation area 10 located in the neighborhood of the dielectric material 4. As a result, a treating substrate 9 heated on the stage at a predetermined temperature is subjected to terminal treatment by hydrogen active species transported from the plasma generation area 10 to the stage 8 by gas stream.

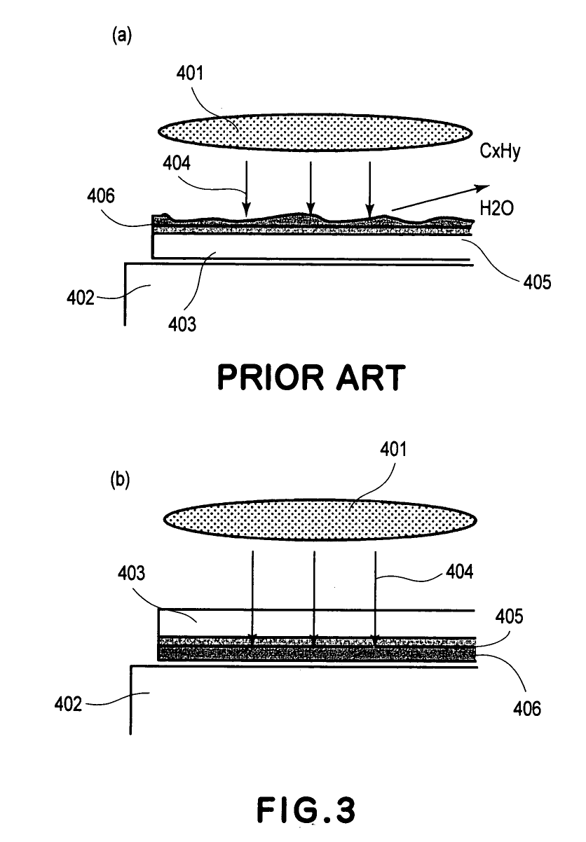

FIG. 2 is a graph showing an etching rate of a polyimide film during hydrogen plasma treatment, and FIGS. 3(a) and 3(b) are explanatory views for illustrating an effect of terminal treatment by hydrogen plasma with respect to a semiconductor substrate on which the polyimide film is formed as a surface layer.

By using the above described plasma treatment apparatus and method, hydrogen terminal treatment of a device structure portion 405, disposed on a silicon substrate 403 (wafer) mounted on a substrate stage 402, on which a polyimide film 406 is formed as a protective layer, was performed by hydrogen plasma 401 as shown in FIGS. 3(a) and 3(b). The distance WD (shown in FIG. 1) between the dielectric window 4 and the stage 8 was 100 mm, and treatment conditions were a substrate temperature of 275° C., a treatment gas of hydrogen 100%, a gas pressure of 66.5 Pa, and a microwave output of 3 kW.

First, as First Comparative Embodiment, as shown in FIG. 3(a), terminal treatment was performed for 5 minutes in such a state that a surface (to be treated) on the device structure portion 405 side of the silicon substrate 403 is directed toward the hydrogen plasma 401 side. As a result, the polyimide film 406 was considerably etched and no effect of the terminal treatment was attained. It has been known that the hydrogen plasma 401 haws a property of gasifying an organic compound by reduction and exhibits an etching rate depending on a treating temperature even with respect to the polyimide film 406 as the protective film (FIG. 2). More specifically, the reason why the treatment effect is not attained is such that the surface polyimide film 406 of the silicon substrate (wafer) 403 is etched by the hydrogen plasma 401 as hydrocarbons (CxHy) and reduction products, so that hydrogen active species 404 is almost completely consumed in the polyimide film 406, thus failing to reach the device structure portion 405 to be subjected to the terminal treatment.

For this reason, as First Embodiment according to the present invention, as shown in FIG. 3(b), terminal treatment was performed in such a state that the surface on the device structure portion 405 side is directed toward the substrate stage 402 as the substrate holding means and a rear surface of the silicon substrate (wafer) 403 is exposed to the hydrogen plasma 401. As a result, an improvement in transistor characteristic depending on the treating time was observed without substantially causing etching of the polyimide film 406 applied onto the wafer 403 surface (via the device structure portion 405). This may be considered because the hydrogen active species 404 irradiated from the rear surface side of the wafer 403 diffuses into Si crystal to reach the device structure portion 405, so that the terminal treatment is performed without being adversely affected by the surface polyimide film 406.

### (Second Embodiment and Second Comparative Embodiment)

As Second Comparative Embodiment, a wafer on which a solid-state image sensing device was formed was fixed on a treatment stage so that a rear surface thereof is directed toward the treatment stage similarly as in the conventional plasma treatment method, and then was subjected to terminal treatment.

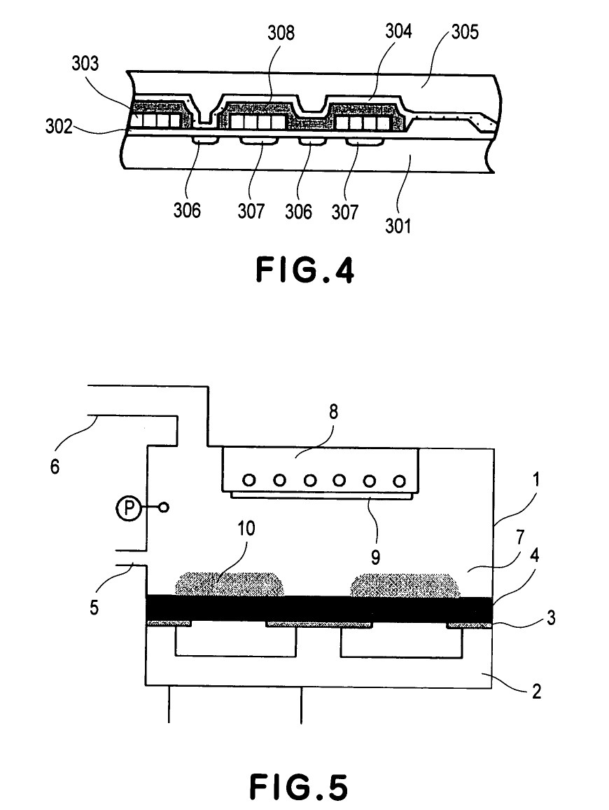

Referring to FIG. 4, on a semiconductor silicon substrate 301, a light receiving element 306 and a transfer register 307 for transferring electric charges which has been subjected to photoelectric conversion by the light receiving element 306 are formed and thereon, a transfer electrode 303 is formed through an insulating film 302. On the insulating film 302 and the transfer electrode 303, a light-blocking layer 308 of aluminum is disposed in order to form an optical black (OPB) area used for reference of a black level and prevent smear, i.e., light from entering the transfer register 307. Further, on the light-blocking layer 308, a surface protective layer 304 therefor and a flattening layer 305 covering the surface protective layer 304.

The terminal treatment with hydrogen plasma was performed under the same conditions as in First Embodiment except that the treatment time was changed to 10 minutes, by using the same plasma treatment apparatus as in First Embodiment.

However, in a light receiving area where the light-blocking layer 308 was not formed, a dark current was decreased by the terminal treatment. On the other hand, immediately under the OPB area, an effect of the terminal treatment was not attained at all, so that the resultant dark current was different from that in the light receiving area.

This may be attributable to the use of a titanium nitride layer as a reflection prevention layer at the surface of the light-blocking aluminum layer. More specifically, the titanium nitride generally has a high affinity for the hydrogen active species, so that it is used as a hydrogen-blocking material. Also in this comparative embodiment, the terminal treatment is carried out in such a state that the hydrogen active species is transferred from the outermost surface of the treating substrate (the surface close to the device portion) toward the device portion, so that it can be considered that the hydrogen active species cannot reach the device portion immediately under the titanium nitride portion of the light-blocking layer.

For this reason, as Second Embodiment according to the present invention, terminal treatment was performed for 10 minutes in such a state that the device-side surface (to be treated) of the solid-state image sensing device was directed toward the treatment stage and a rear surface of the substrate was directed toward an upstream side of the reaction (treatment) gas. As a result, it was possible to attain the effect of decreasing the dark current uniformly at the light-blocking portion and the light receiving portion. Accordingly, there was no change in the terminal treatment effect by the light-blocking layer. This means that the hydrogen active species is transferred from the rear surface side of the substrate 301 to the device portion, whereby the terminal treatment is performed over the entire area without being adversely affected by distribution of the titanium nitride portion formed in the light-blocking layer 308.

According to First and Second Embodiments of the present invention, it is possible to unaffectedly perform the terminal treatment with the hydrogen plasma even in the case where the kind or material of a film as an upper layer of a device structure portion to be subjected to the terminal treatment blocks the hydrogen active species, so that it becomes possible to widely apply the terminal treatment. As a result, it becomes possible to provide a high-performance device.

The effect of the present invention is not limited by the structures of the plasma generation portion, the substrate holding means, and the treatment chamber. A similar effect can be achieved in other structures thereof because the terminal treatment is unaffected by the kind of the upper layer film located on the device structure portion to be treated.

In order to perform the terminal treatment at a higher efficiency, it is desirable that the following embodiments are carried out.

More specifically, as the plasma generation source in the present invention, one which introduces an electric field through a dielectric window is used, whereby it becomes possible to perform the terminal treatment with high clean plasma. Further, by using a substrate holding means provided with a heating mechanism, it is possible to further enhance a transfer efficiency of the hydrogen active species compared with the case of using a substrate holding means having no heating mechanism.

In the present invention, it is also possible to employ such a method that the treating substrate taken out from a carrier is turned upside down by a mechanism of turning over the treating substrate and then is carried into the treatment chamber described above. Alternatively, as shown in FIG. 5 (in which structural members or means are indicated by the same reference numerals as in FIG. 1), it is also possible to employ such an embodiment in which the treating substrate 9 taken out from the carrier is carried into the treatment chamber without being turned upside down and is fixed to the stage 8 with the substrate holding surface directed downward.

Further, the treating substrate may be accommodated in the carrier in such a state that it is turned upside down in advance by a transfer machine etc. It is also possible to employ such an embodiment in which a mechanism of turning over the treating substrate is provided in the same apparatus and the treating substrate is turned upside down by the mechanism after being taken out from the carrier.

Further, in the present invention, a temperature of the treating substrate is controlled by the heating mechanism provided to the substrate holding means, whereby it is possible to effect the terminal treatment with a good reproducibility.

In the present invention, when the terminal treatment is performed in such a manner that the dielectric window is disposed in parallel with the substrate holding means, such as the stage or the substrate mounting table, with a certain distance WD and a high-density plasma having a density of not less than 1×10¹¹ cm⁻³ is generated by introducing the microwave through the dielectric window, it is possible to efficiently irradiate the treating substrate with high-density hydrogen active species. As a means for providing the high-density plasma, it is possible to use a slot antenna or provide a high power microwave.

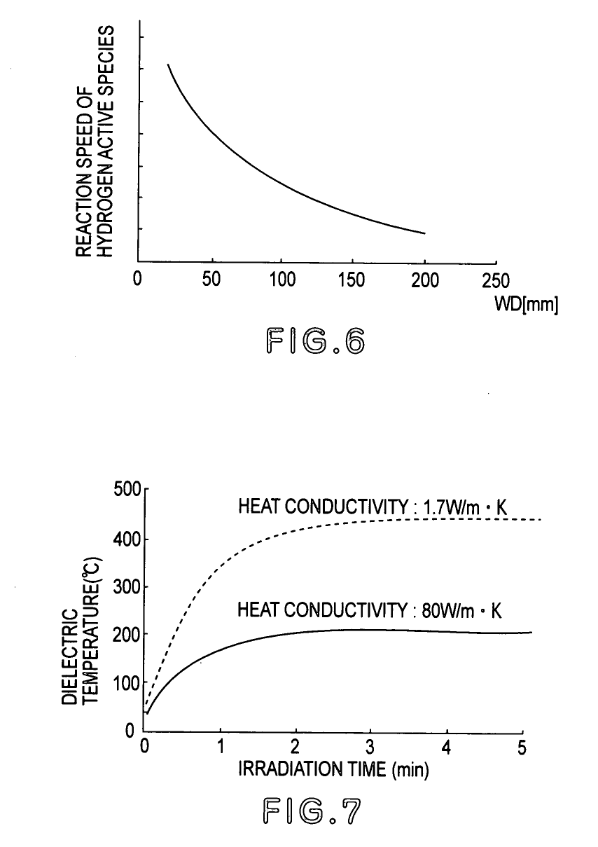

The hydrogen active species is deactivated by collision of molecules with each other during the process of transferring it from the plasma generation area 10, so that the density of the hydrogen active species varies largely depending on the distance WD between the stage 8 and the dielectric window 4. FIG. 6 is a graph showing a relationship between a film thickness-decreasing speed by reduction (reaction speed of hydrogen active species) and a distance WD in the case where an organic material used in a resist is irradiated with hydrogen plasma. As shown in FIG. 6, as the distance becomes smaller, a higher density hydrogen active species reaches the treating substrate.

However, when the distance WD is less than 20 nm, the treating substrate and the plasma generation area come close to each other so that damage by hydrogen active species having excessively high energy becomes undesirably large. Accordingly, in the present invention, the distance WD capable of achieving an effective terminal treatment effect is not less than 20 nm and not more than 200 nm. The distance WD may preferably be not less than 50 nm and not more than 150 nm as a condition for realizing a higher treatment efficiency and a lower damage in combination.

The treatment temperature may preferably be not more than 400° C. This is because when the treatment temperature is excessively high, as pointed out in JP-A Hei 05-243273, elimination of hydrogen from the treating substrate which has been subjected to the hydrogen terminal treatment is caused to occur, thus lowering the treatment efficiency.

The dielectric window 4 is directly exposed to the plasma generation area, so that there is a possibility that the treating substrate temperature is excessively increased indirectly by excessive temperature rise in the case of using a material having a low thermal conductivity. FIG. 7 shows data obtained by measuring an increasing temperature of the dielectric window during hydrogen plasma irradiation in such a state that the chamber is opened immediately after the plasma irradiation. The measurement is performed by opening the chamber, so that it is considered that the temperature during the irradiation becomes high. However, it becomes possible to suppress the dielectric window temperature to not more than 300° C. even during the plasma irradiation by using a material such as aluminum nitride, having a thermal conductivity of not less than 70 W/m.K as a material for the dielectric window. As a result, it is possible to obviate a lowering in the temperature efficiency by the excessive heating of the treating substrate as described above.

The temperature pressure may preferably be not less than 13 Pa and not more than 665 Pa. The hydrogen gas has an ionization cross section smaller than gasses such as oxygen and nitrogen, thus providing a poor plasma ignitability. For this reason, when the treatment pressure is excessively decreased to less than 13 Pa, there is a possibility that such a low treatment pressure becomes an unstable factor of the treatment, and at the same time, the resultant hydrogen active species has a long mean free path, so that there is a possibility that hydrogen active species having energy more than necessary reaches the treating substrate. As a result, the device structure portion can be damaged by, e.g., charge-up. On the other hand, when the treatment pressure is excessively increased to more than 665 Pa, there is a possibility that the hydrogen active species is deactivated until it reaches the treating substrate.

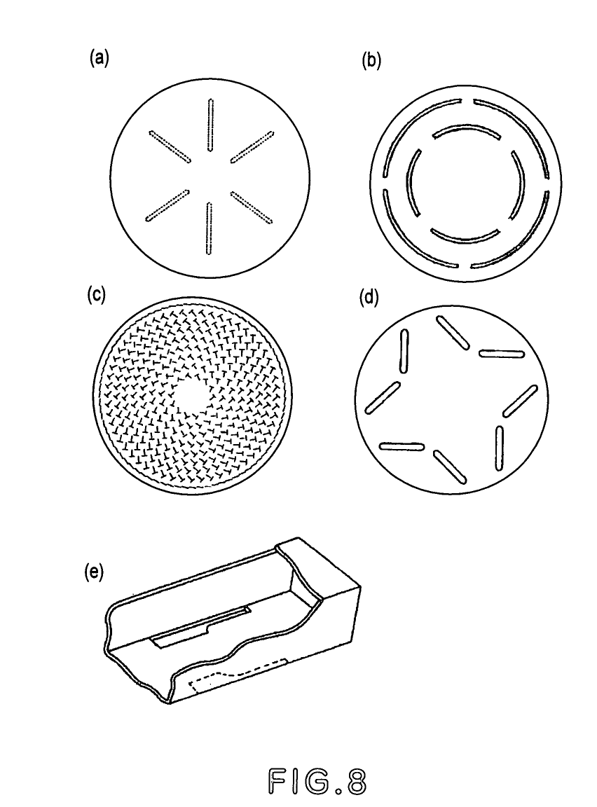

In the present invention, by introducing the microwave into the above described dielectric material through an antenna plate having at least one slot, it becomes possible to readily control in-plane uniformity. As the antenna plate, other than an antenna plate having radial slots, shown in FIG. 8(a), used in the above described embodiments, it is also possible to employ antenna plates having slots different from the radial slots as shown in FIGS. 8(b), 8(c) and 8(d). More specifically, the antenna plate shown in FIG. 8(b) has arcuate slots provided along concentric circles. The antenna plate shown in FIG. 8(c) has a multiplicity of small slots arranged in a scattered form. The antenna plate shown in FIG. 8(d) has such slots that they are located along lines which are inclined at certain angles with respect to virtual radial lines. Further, it is also possible to use a rectangular waveguide provided with slots at its side surface as shown in FIG. 8(e).

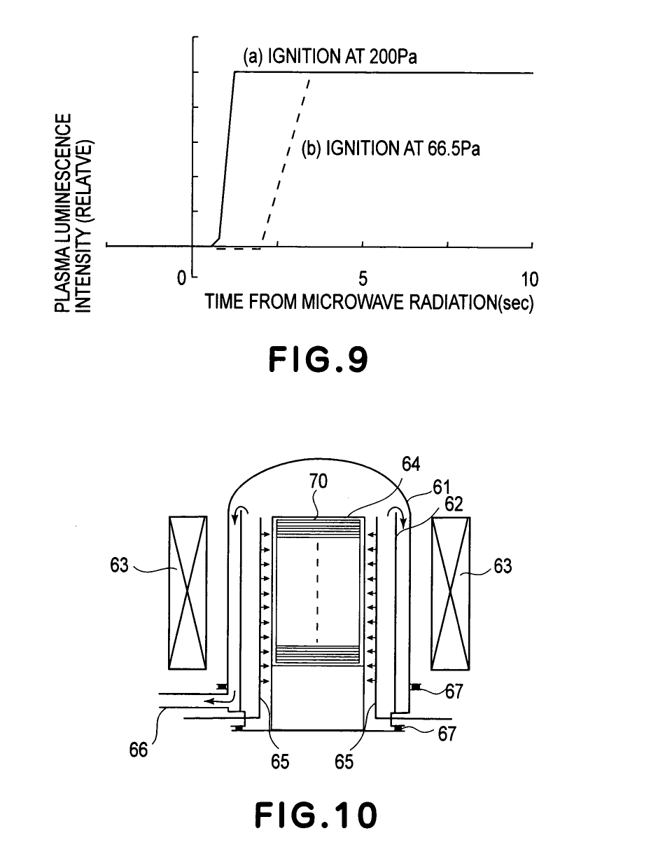

Further, as described above, the hydrogen gas has such a disadvantage that it has the smaller ionization cross section than oxygen gas etc., thus exhibiting a poor ignitability. As a result, thus exhibiting a poor ignitability. As a result, in some cases, there is a time lag from the microwave radiation to the plasma ignition. In this case, as shown in FIG. 9, the plasma ignition can be stabilized to ensure a process reproducibility by performing the plasma ignition at a pressure higher than the treatment pressure. Alternatively, addition of rare gas having a relatively good plasma ignitability is also effective in improving the process reproducibility.

Further, as shown in FIG. 10, it is also possible to treat a plurality of substrates at the same time by using a batch-type plasma treatment apparatus.

With respect to a method of fixing the treating substrate, when the substrate holding means is provided in the treatment chamber and the treating substrate is fixed in such a state that a surface close to the device structure portion is directed toward the substrate holding means, it is possible to effectively suppress not only overheating of the treating substrate by the plasma treatment but also the irradiation of the substrate surface with the hydrogen active species. Accordingly, in the case where the treating substrate is adversely affected by the hydrogen plasma treatment from its surface as in the above described embodiments, it is possible to prevent the adverse effect.

In FIG. 10, the batch-type plasma treatment apparatus includes an outer quartz tube 61 and an inner quartz tube 62 which constitute a vacuum chamber; heaters 63 disposed along an outer peripheral surface of the vacuum chamber; a substrate holding member 64, disposed in the vacuum chamber, as a substrate holding means for holding a plurality of substrates; treatment gas guiding nozzles 65 for guiding the treatment gas into the vacuum chamber; an exhaust pipe 66 for exhausting the inside of the vacuum chamber; O-rings 67 for hermetically sealing respective connecting portions; and a plurality of treating substrates 70 in such a state that they are disposed with a spacing between opposing surfaces of adjacent substrates, and a surface of each substrate support, i.e., a rear surface opposite from the surface to be treated, is directed toward an upstream direction of the treatment gas.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 409764/2003 filed Dec. 9, 2003, which is hereby incorporated by reference.

1. A plasma treatment method for treating a surface, to be treated, of a substrate by using plasma of a treatment gas including hydrogen atom, said method comprising:
a treatment step of treating the substrate in such a state that a rear surface, opposite from the surface to be treated, of the substrate is disposed toward an upstream direction of the treatment gas.

2. A method according to claim 1, wherein said treatment step is a terminal treatment step of treating a dangling band.

3. A method according to claim 1, wherein the treatment gas comprises at least one species of gas selected from the group consisting of hydrogen gas, water vapor, and ammonia.

4. A method according to claim. 1, wherein the substrate comprises a material containing, as a constituent, at least a substance containing nitrogen or carbon.

5. A method according to claim 1, wherein the substrate comprises a material containing, as a constituent, at least a substance containing a group IVA element or a group VIII element.

6. A method according to claim 1, wherein the substrate comprises a material containing, as a constituent, at least a metal oxide.

7. A method according to claim 1, wherein said treatment step is performed in such a condition that a temperature of substrate holding means is not more than 400° C.

8. A method according to claim 1, wherein said treatment step is performed in such a condition that a pressure is not less than 13 Pa and not more than 665 Pa.

9. A method according to claim 1, wherein in said treatment step, the plasma is ignited at a pressure higher than a treatment pressure and the pressure is then lowered to the treatment pressure.

10. A method according to claim 1, wherein in said treatment step, a rare gas is added at least at the time of ignition of the plasma.

11. A plasma treatment apparatus for treating a surface, to be treated, of a substrate, comprising:
a gas supply portion for supplying a treatment gas including hydrogen atom, and
a substrate holding apparatus for holding the substrate so that the surface to be treated is disposed toward an upstream direction of the treatment gas in a chamber.

12. An apparatus according to claim 11, wherein said apparatus further comprises a substrate conveyance apparatus for conveying the substrate to said substrate holding apparatus so that the surface to be treated is disposed toward said substrate holding apparatus when the substrate is conveyed to said substrate holding apparatus.

13. An apparatus according to claim 11, wherein the chamber comprises therein a substrate heating mechanism for heating the substrate to a predetermined temperature, and a dielectric window which is provided in order to introduce an electric field into the chamber and constitutes at least-a part of a wall constituting a gas tight structure of the chamber.

14. An apparatus according to claim 13, wherein the dielectric window is disposed in parallel with said substrate holding means.

15. An apparatus according to claim 13, wherein a microwave is introduced into a surface of the dielectric window to generate a surface wave electric field, and treatment is performed by plasma, obtained by ionizing the treatment gas in the electric field, at a density of not less than 1×10¹¹ cm⁻³.

16. An apparatus according to claim 13, wherein a distance between the dielectric window and said substrate holding means is not less than 20 mm and not more than 200 mm.

17. An apparatus according to claim 13, wherein the dielectric window has a thermal conductivity of not less than 70 W/m.K.
